(19) United States
(12) Patent Application Publication
(10) Pub. No.: US 2024/0303389 A1
(43) Pub. Date: Sep. 12, 2024

(54) DATA GENERATION APPARATUS, DATA GENERATION METHOD, NON-TRANSITORY COMPUTER READABLE MEDIUM AND MAGNETIC RESONANCE IMAGING APPARATUS

(71) Applicant: Canon Medical Systems Corporation, Otawara-shi (JP)

(72) Inventor: Hidenori TAKESHIMA, Tokyo (JP)

(73) Assignee: Canon Medical Systems Corporation, Otawara-shi (JP)

(21) Appl. No.: 18/515,379

(22) Filed: Nov. 21, 2023

(30) Foreign Application Priority Data
Mar. 6, 2023 (JP) 2023-033886

(51) Int. Cl. G06F 30/20; G01R 33/54

(52) U.S. Cl. CPC G06F 30/20; G01R 33/543

(57) ABSTRACT

According one embodiment, a data generation apparatus includes processing circuitry. The processing circuitry is configured to obtain an operation instruction based on a user operation on an image diagnostic apparatus or an image diagnostic apparatus simulator. The processing circuitry is configured to convert the operation instruction into an internal instruction relating to hardware control of the image diagnostic apparatus or the image diagnostic apparatus simulator from which the operation instruction has been obtained. The processing circuitry is configured to generate simulation data by executing a physical simulation using the internal instruction.

### CROSS-REFERENCE TO RELATED APPLICATIONS

This application is based upon and claims the benefit of priority from Japanese Patent Application No. 2023-033886, filed Mar. 6, 2023, the entire contents of which are incorporated herein by reference.

### FIELD

Embodiments described herein relate generally to a data generation apparatus, a data generation method, a non-transitory computer readable medium, and a magnetic resonance imaging apparatus.

### BACKGROUND

A simulator configured to simulate data that would be acquired by a medical image diagnostic apparatus is known. Examples include an MRI simulator, which simulates an operation of a magnetic resonance imaging (MRI) apparatus by numerically analyzing a magnetic resonance phenomenon using Bloch equations. Another example is a CT simulator, which generates projection data acquired by an X-ray computed tomography (CT) apparatus by numerically simulating a linear attenuation coefficient at the time of irradiation of a subject with X-rays.

However, pulse sequences for, for example, acquiring magnetic resonance signals (MR signals) set in an MRI simulator, which are designed for the MRI simulator, cannot precisely reproduce the behavior of an actual MRI apparatus, and often do not match data that would be obtained by the actual MRI apparatus. Thus, reproducibility of simulation data relative to data that would be obtained by an actual MRI apparatus becomes a problem at the time of utilization of simulation data as training data in machine learning.

### BRIEF DESCRIPTION OF THE DRAWINGS

FIG. 1 is a block diagram showing a data generation apparatus according to the present embodiment.

FIG. 2 is a flowchart showing an operation of the data generation apparatus according to the present embodiment.

FIG. 3 shows a first example of a conversion process of converting an operation instruction into an internal instruction.

FIG. 4 shows a second example of a conversion process of converting an operation instruction into an internal instruction.

FIG. 5 shows a third example of a conversion process of converting an operation instruction into an internal instruction.

FIG. 6 shows details of an MRI apparatus on which the data generation apparatus and a simulator are installed.

### DETAILED DESCRIPTION

In general, according to one embodiment, a data generation apparatus includes processing circuitry. The processing circuitry is configured to obtain an operation instruction based on a user operation on an image diagnostic apparatus or an image diagnostic apparatus simulator. The processing circuitry is configured to convert the operation instruction into an internal instruction relating to hardware control of the image diagnostic apparatus or the image diagnostic apparatus simulator from which the operation instruction has been obtained. The processing circuitry is configured to generate simulation data by executing a physical simulation using the internal instruction.

Hereinafter, the data generation apparatus, the data generation method, the non-transitory computer readable medium, and the magnetic resonance imaging apparatus according to the present embodiment will be described with reference to the drawings. In the embodiments to be described below, elements assigned the same reference symbols are assumed to perform similar operations, and redundant descriptions will be omitted where unnecessary. An embodiment will be described below with reference to the accompanying drawings.

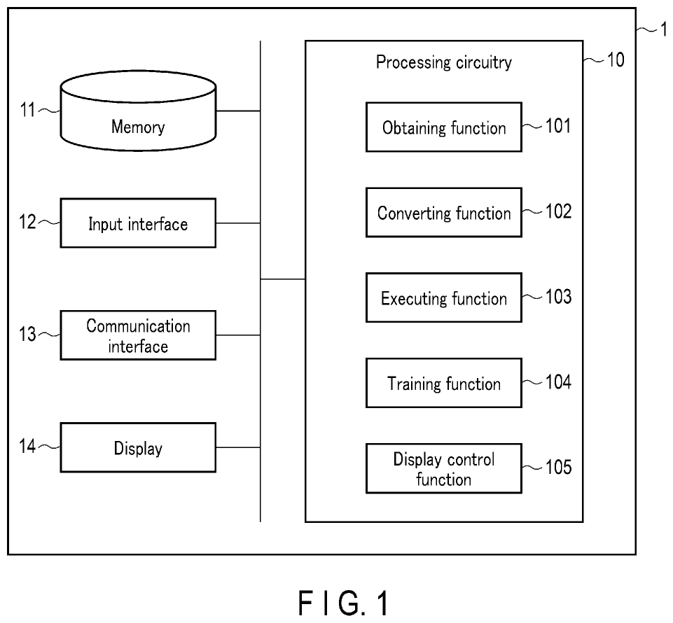

The data generation apparatus according to the present embodiment will be described with reference to the block diagram of FIG. 1.

A data generation apparatus 1 is a computer including processing circuitry 10, a memory 11, an input interface 12, a communication interface 13, and a display 14.

The processing circuitry 10 includes a processor such as a CPU as a hardware resource. The processing circuitry 10 implements, through execution of various programs, an obtaining function 101, a converting function 102, an executing function 103, a training function 104, and a display control function 105.

The obtaining function 101 obtains an operation instruction based on a user operation performed on an image diagnostic apparatus or an image diagnostic apparatus simulator. The image diagnostic apparatus simulator is a simulator that simulates a physical phenomenon using a numerical simulation. Hereinafter, it is assumed that the image diagnostic apparatus is a magnetic resonance imaging (MRI) apparatus, and that the image diagnostic apparatus simulator is an MR simulator based on the Bloch equations, unless otherwise specified.

The image diagnostic apparatus is not limited to an MRI apparatus, and may be any other medical image diagnostic apparatuses such as an X-ray computed tomography (CT) apparatus, an ultrasonic diagnostic apparatus, or a positron-emission tomography (PET) apparatus. The image diagnostic apparatus simulator may be any physical simulator (numerical simulator) corresponding to the image diagnostic apparatus.

The converting function 102 converts the operation instruction into an internal instruction relating to control of hardware installed on the image diagnostic apparatus or image diagnostic apparatus simulator from which the operation instruction has been obtained.

The executing function 103 executes a physical simulation using the internal instruction, and generates simulation data.

The training function 104 generates a trained model by training a machine learning model using the generated simulation data as training data.

The display control function 105 controls the display 14 to display various types of data such as simulation data and data relating to the operation instruction obtained by the obtaining function 101, as well as a graphical user interface (GUI).

The memory 11 is a storage device configured to store a variety of information, such as a hard disk drive (HDD), a solid-state drive (SSD), an integrated circuit memory device, etc. Also, the memory 11 may also be a drive, etc. configured to read and write a variety of information to and from a CD-ROM drive, a DVD drive, a portable storage medium such as a flash memory, etc. The memory 11 stores, for example, medical data, control programs, etc. that have been acquired in the past.

The input interface 12 includes an input device that accepts various instructions from the user. For the input device, a keyboard, a mouse, various types of switches, a touch screen, a touch pad, etc. may be employed. The input device is not limited to a device including physical operational components, such as a mouse and a keyboard. Examples of the input interface 12 include electrical signal processing circuitry configured to receive an electrical signal corresponding to an input operation from an external input device provided separately from the magnetic resonance imaging apparatus and output the received electrical signal to various circuits. Also, the input interface 12 may be a speech recognition device configured to convert an audio signal acquired by a microphone into an instruction signal.

The communication interface 13 is an interface

configured to connect, via a local area network (LAN) , etc., the magnetic resonance imaging apparatus with a work station, a picture archiving and communication system (PACS), a hospital information system (HIS), a radiology information system (RIS), and the like. The communication interface 13 transmits and receives various types of information to and from the work station, the PACS, the HIS, and the RIS to which the communication interface 13 is connected.

The display 14 displays various information. For the display 14, a CRT display, a liquid crystal display, an organic EL display, an LED display, a plasma display, or any other display known in the present technical field, for example, may be suitably employed.

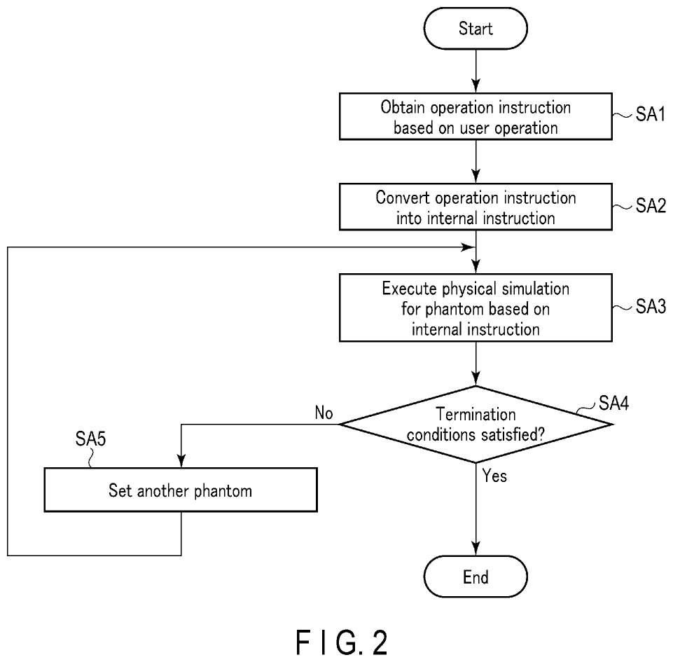

Next, an operation example of the data generation apparatus 1 according to the present embodiment will be described with reference to a flowchart of FIG. 2.

At step SA1, with the obtaining function 101, the processing circuitry 10 obtains an operation instruction based on a user operation. It is assumed that a user operation is, for example, a keyboard input by an engineer to a console of an MRI apparatus to set and input imaging conditions such as parameters. Specifically, imaging conditions may be set in such a manner that the type of imaging sequence is a spin echo technique, and TE=10 [msec], TR=500 [msec], etc. are set as parameters relating to acquisition of magnetic resonance signals (hereinafter, “MR signals”). The set imaging conditions are obtained as an operation instruction.

At step SA2, the processing circuitry 10 converts, with the converting function 102, the operation instruction into an internal instruction relating to hardware control. It is assumed, for example, that the user selects a spin-echo technique for imaging sequences, and sets TE=20 [msec]. If a subject is irradiated with an excitation pulse of a 90-degree Flip angle (FA), the user (e.g., an engineer) sets desired imaging conditions without taking into consideration control of hardware itself such as a transmitter coil. That is, how magnitudes of a voltage and a current applied to the transmitter coil (or logical values corresponding to their physical quantities), their application times, etc. are varied to realize an excitation pulse of a 90-degree Flip angle, and from which position to which position is regarded as TE to realize TE=20 [msec] is determined depending on the vendor and on the apparatus. On the other hand, hardware is operated based on control performed as to what voltage and what current are applied at what timing, rather than on setting of parameters specified by imaging conditions such as an excitation pulse of a 90-degree Flip angle and TE=20 [msec].

In another example, even if a predetermined TR is given as an operation instruction in, for example, gate control in electrocardiogram gated imaging, the imaging is not necessarily performed at a constant TR in hardware control due to fluctuations of the heartbeat of the subject.

Accordingly, in this example, an instruction (also referred to as a “low-level instruction”) for the hardware itself in an MRI apparatus, such as magnitudes of a voltage generated in a high-voltage generator and a current applied to a transmitter coil for realizing an operation instruction relating to setting of imaging conditions, such as an excitation pulse of a 90-degree Flip angle and TE=20 [msec], or logical values associated with the magnitudes of the voltage and the current, as well as their application times, is obtained as an internal instruction. An internal instruction includes an instruction for a particular compartment supplied to hardware driven to realize an operation instruction, such as magnitudes and application times of a voltage and a current, a frequency of an RF signal, and a field strength of a gradient field, for example, “timestamp=10000 us, duration=3000 us, RFdata=(float array) Hz, Gzdata=(float array) Hz/m”. It is to be noted that a “float array” refers to data that reproduces waveforms.

Moreover, an internal instruction may be an instruction for a specific hardware of the image diagnostic apparatus obtained by extracting an instruction for a transmitter coil of an RF signal, such as “timestamp=10000 us, duration=3000 us, and RFdata=(float array) Hz”, from instructions of the above-described specific compartment. Furthermore, a low-level language such as an assembly code may be obtained as an internal instruction, or an execution file name such as “FE2D_seq.exe” may be obtained as an internal instruction. Furthermore, sets of script names and parameter values of a generation module such as “FE2D.py, FA=90, TE=10, TR=500, . . . ” may be obtained as an internal instruction.

That is, an internal instruction may be in any expression format as long as it is an instruction for executing hardware. With the converting function 102, the processing circuitry 10 obtains, as an internal instruction, an instruction in at least one of the above-described internal instruction formats based on the operation instruction, thereby converting the operation instruction into an internal instruction. It is to be noted that, with the converting function 102, the processing circuitry 10 may record the internal instruction in the memory 11.

At step SA3, with the executing function 103, the processing circuitry 10 executes a simulation based on the internal instruction, and generates simulation data. In this example, simulation data of the MR data is obtained by setting phantom data such as numerical phantoms and voxel phantoms, and numerically solving Bloch equations phenomenologically describing magnetic resonance with respect to magnetization of virtual hydrogen atoms representing a plurality of hydrogen atoms in a virtual manner. Examples of the phantom data include physical quantities of a type such as a value MO proportional to the number of protons, a longitudinal relaxation time T1, a transverse relaxation time T2, a resonant frequency F0, and a diffusion coefficient D. It is to be noted that a simulation may be executed using both an operation instruction and a corresponding internal instruction. Also, the processing circuitry 10 may execute, with the executing function 103, part of the internal instruction.

At step SA4, the executing function 103 determines whether or not the processing circuitry 10 satisfies termination conditions. As an example of satisfying the termination conditions, it can be determined that the termination conditions are satisfied if a predetermined number of physical simulations have been performed for a plurality of types of phantom data. If the termination conditions are satisfied, the processing is terminated, and if the termination conditions are not satisfied, the processing advances to step SA5.

At step SA5, with the executing function 103, the processing circuitry 10 sets another item of phantom data in which at least some of the values are different from those of the phantom data at the time of execution of the previous simulation. Thereafter, the processing returns to step SA3, at which similar processing is repeated for said another item of phantom data.

In processing from step SA3 to step SA5, a case has been assumed where a plurality of processes are executed for a single internal instruction using a plurality of different items of phantom data, thereby generating a plurality of different items of simulation data; however, the data generation process shown in FIG. 2 may be performed using a single item of phantom data, thereby generating a single item of simulation data.

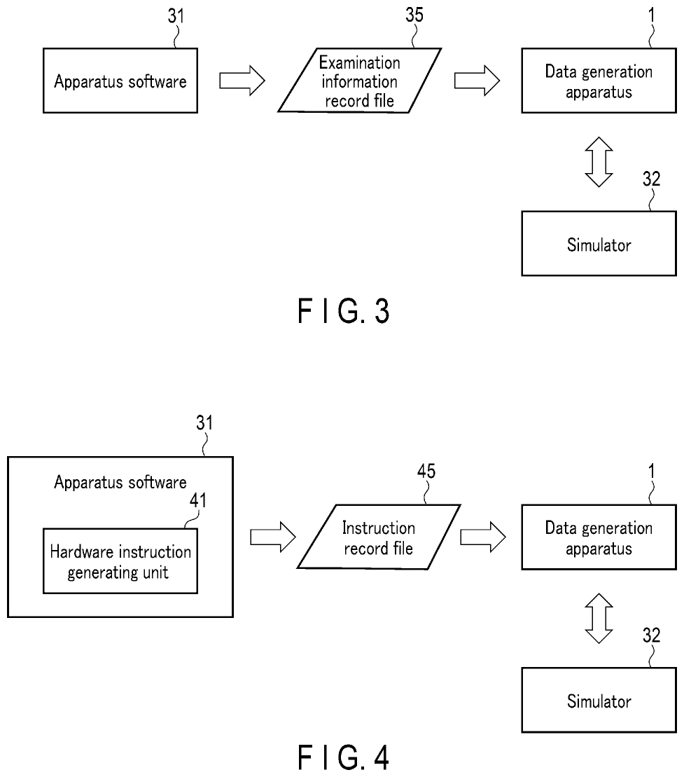

Next, a first example of a conversion process of converting an operation instruction into an internal instruction will be described with reference to a conceptual diagram of FIG. 3.

In a first example, apparatus software 31 installed on an image diagnostic apparatus (an MRI apparatus in this example) outputs a user's operation instruction as an examination information record file 35, which is a log file. A case is assumed where, for example, the apparatus software 31 sets imaging conditions based on a user input. In this case, an operation instruction including a sequence type, a parameter value, etc. based on the set imaging conditions is output as the examination information record file 35.

The data generation apparatus 1 obtains the examination information record file 35, and the processing circuitry 10 converts, with the converting function 102, the operation instruction contained in the examination information record file 35 into an internal instruction. If, for example, the operation instruction relates to imaging based on a spin echo, the operation instruction is mapped to an internal instruction on how an excitation pulse, an inversion pulse, and a gradient field in each axis are realized in terms of hardware, in an MRI apparatus on which the apparatus software 31 is installed. For the mapping, operation instructions and internal instructions are stored in advance as a correspondence table, for example, in the memory 11, and the processing circuitry 10 obtains, with the converting function 102, an internal instruction corresponding to the operation instruction recorded in the examination information record file 35 by referring to the correspondence table.

The data generation apparatus 1 inputs the internal instruction together with the operation instruction to the simulator 32. The simulator 32 executes a physical simulation, and outputs simulation data to the data generation apparatus 1. With such a configuration, the apparatus software 31 installed on an MRI apparatus merely outputs the examination information record file in accordance with the operation instruction, and does not need to modify the apparatus software 31 so as to output an internal instruction relating to hardware.

Next, a second example of a conversion process of converting an operation instruction into an internal instruction will be described with reference to a conceptual diagram shown in FIG. 4.

In the second example, the apparatus software 31 includes a hardware instruction generating unit 41 for outputting an internal instruction to the apparatus software 31. The hardware instruction generating unit 41 is, for example, a device driver/library, and outputs a hardware instruction based on an operation instruction received by the apparatus software 31 from the user as an instruction record file 45, which is a log file.

The data generation apparatus 1 receives the instruction record file 45, inputs a hardware instruction included in the instruction record file 45 to the simulator 32, executes a physical simulation, and thereby generates simulation data. While, in this case, the hardware instruction generating unit 41 needs to be modified to make an output, it is possible to generate simulation data with high reproducibility of the behavior of the actual apparatus on which the apparatus software 31 is installed.

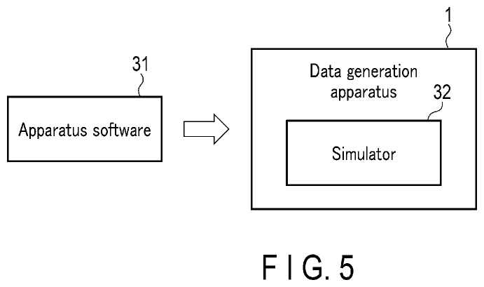

Next, a third example of a conversion process of converting an operation instruction into an internal instruction will be described with reference to a conceptual diagram shown in FIG. 5.

In the third example, the data generation apparatus 1 includes a simulator 32, and an internal instruction to apparatus software based on an operation instruction is directly recorded by the data generation apparatus 1, and input to the simulator 32. The internal instruction based on the operation instruction input to the apparatus software 31 may be input to the data generation apparatus 1 via communication methods, or may be input via an in-process link. In the case of using communication methods, input may be made via either TCP/IP or an Inter-Process Communication (IPC). In the case of an in-process link, a link or a code program may be incorporated by a dynamic link library (DLL), etc.

In this case, it is possible to execute a simulation with high reproducibility, without the need to modify the apparatus software 31.

Next, a case will be described where simulation data generated using the data generation apparatus 1 according to the present embodiment is used as training data.

The user performs imaging of a phantom or a subject in an MRI apparatus. Subsequently, the data generation apparatus 1 uses an internal instruction corresponding to the imaging to reproduce the same internal instruction for a plurality of different items of phantom data, thereby executing a physical simulation on a simulator. Thereby, the same number of items of simulation data as the number of items of phantom data can be generated.

The generated simulation data is used as training data for a machine learning model. The machine learning model may be any model generally used in machine learning, such as a deep convolutional neural network.

Specifically, the machine learning model is trained taking the simulation data as input data and using a denoised reconstruction image (MR image) as correct data. Through the training of the machine learning model, a trained model for a denoising task can be generated. The task of the machine learning is not limited to denoising, and machine learning assuming a task disclosed in Hidenori Takeshima, “Deep Learning and Its Application to Function Approximation for MR in Medicine: An Overview”, Sep. 17, 2021, Magnetic Resonance in Medical Sciences, for example, may be performed. By using the simulation data as training data, the reproducibility of the simulation data becomes high, thus allowing the training data to be enhanced with high efficiency and high precision.

In the above-described example, simulation data relating to an MRI apparatus and MR data has been assumed; however, it is possible to improve the precision to a level that allows the output of the simulator to be close to the output of the actual apparatus, with respect to the other medical image diagnostic apparatuses such as an X-ray CT apparatus and X-ray projection data.

In the case of, for example, a physical simulator relating to an X-ray CT apparatus, imaging parameters such as a tube voltage, a tube current, a field of view (FOV), and the number of views, as well as a desired amount of noise or a desired SD value, are input to the simulator. A simulator executes simulated irradiation of a phantom with X-rays based on the imaging parameters. Thereby, simulation data of the projection data, which is projection of a linear attenuation coefficient of the phantom, is generated. It is to be noted, however, that automatic exposure control (AEC) is executed during helical scanning or conventional scanning in view of the thickness of the subject if scanning by an actual X-ray CT apparatus is assumed, and that an individual difference in an amount of noise among the X-ray CT apparatuses may occur due to photoelectric conversion efficiency of X-rays detected by the X-ray detector.

Accordingly, by obtaining an internal instruction for hardware such as an X-ray tube and an X-ray detector of an X-ray CT apparatus and executing a physical simulation in a simulator similarly to the MRI apparatus, the simulation data of the projection data can be made close to the projection data that would be obtained by the actual X-ray CT apparatus, thereby improving the reproducibility of the simulation data.

It is also possible to train a machine learning model using simulation data generated by acquiring an internal instruction of the image diagnostic apparatus on which the data generation apparatus 1 according to the present embodiment is installed. It is thereby possible to generate simulation data and a trained model specialized for a unit facility in which the image diagnostic apparatus is installed, or a unit user such as an engineer who operates the image diagnostic apparatus.

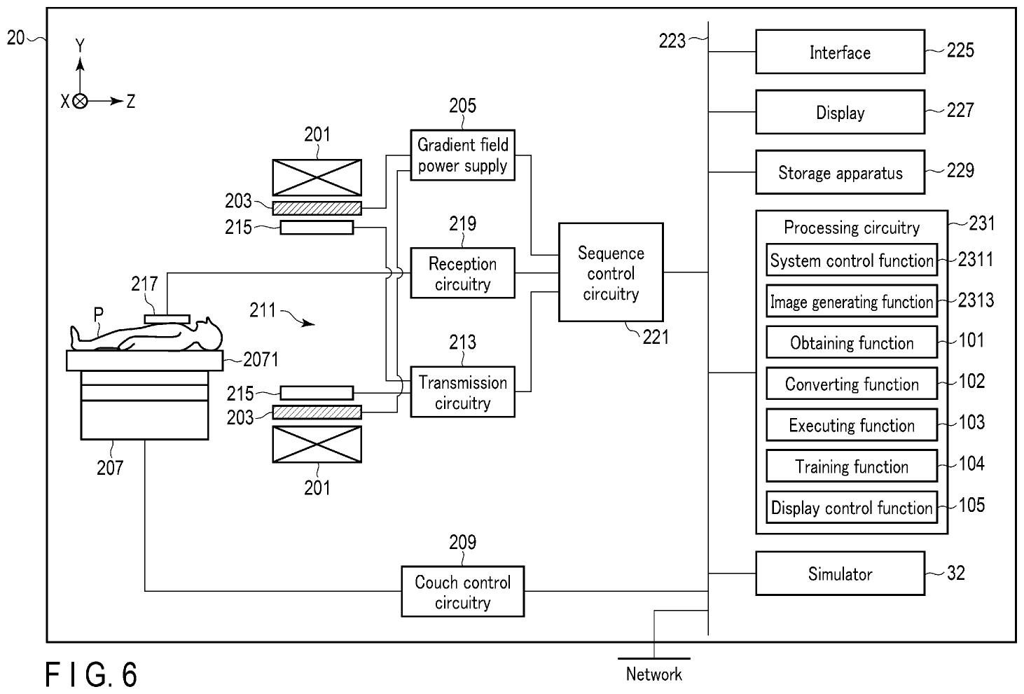

Details of the MRI apparatus on which a data generation apparatus and a physical simulator are installed will be specifically described with reference to a block diagram in FIG. 6.

The MRI apparatus 20 includes a static field magnet 201, a gradient field coil 203, a gradient field power supply 205, a couch 207, couch control circuitry 209, transmission circuitry 213, a transmitter coil 215, a receiver coil 217, reception circuitry 219, sequence control circuitry 221, a bus 223, an interface 225, a display 227, a storage apparatus 229, processing circuitry 231, and a simulator 32. The MRI apparatus 20 may include a hollow, cylindrical shim coil provided between the static field magnet 201 and the gradient field coil 203.

The static field magnet 201 is a magnet formed in a hollow, approximately cylindrical shape. The static field magnet 201 is not necessarily in an approximately cylindrical shape, and may be formed in an open shape. The static field magnet 201 generates a uniform static field in the inner space. In the present embodiment, it is assumed that the static field magnet 201 is a superconducting magnet that uses a superconducting coil.

The gradient field coil 203 is a coil formed in a hollow, cylindrical shape. The gradient field coil 203 is arranged inside the static field magnet 201. The gradient field coil 203 is formed of a combination of three coils respectively corresponding to X, Y, and Z axes that are orthogonal to each other. The Z-axis direction is defined as the same as the orientation of the static field. It is assumed that the Y-axis direction is a vertical direction, and the X-axis direction is a direction perpendicular to both the Z and Y axes. The three coils of the gradient field coil 203 individually receive an electric current supplied from the gradient field power supply 205 and respectively generate gradient fields in which the field strength changes along each of the X, Y and Z axes.

The gradient fields along each of the X, Y, and Z axes generated by the gradient field coil 203 respectively form, for example, a gradient field for frequency encoding (readout gradient field), a gradient field for phase encoding, and a gradient field for slice selection. The frequency encoding gradient field is employed to vary the frequency of an MR signal in accordance with the spatial position. The gradient field for phase encoding is employed to change the phase of an MR signal in accordance with the spatial position. The gradient field for slice selection is employed to determine an imaging slice.

The gradient field power supply 205 is a power supply apparatus that supplies an electric current to the gradient field coil 203 under the control of the sequence control circuitry 221.

The couch 207 is an apparatus that includes a couch top 2071 on which a subject P is placed. The couch 207 inserts the couch top 2071 on which the subject P is placed into a bore 211, under the control of the couch control circuitry 209. The couch 207 is, for example, mounted in an examination room where the MRI apparatus 20 is mounted, in such a manner that the longitudinal axis of the couch 207 is parallel to the central axis of the static field magnet 201.

The couch control circuitry 209 is circuitry that controls the couch 207, and drives the couch 207 in response to a user's instructions via the interface 225, thereby moving the couch top 2071 in a longitudinal direction and a vertical direction.

The transmitter coil 215 is an RF coil arranged inside the gradient field coil 203. The transmitter coil 215 generates a transmit RF wave corresponding to a radio-frequency field in response to a Radio Frequency (RF) pulse supplied from the transmission circuitry 213. The transmitter coil 215 is, for example, a whole-body coil. The whole-body coil may be used as a transmitter/receiver coil. A cylindrical RF shield is provided between the whole-body coil and the gradient field coil 203 for magnetically separating these coils.

The transmission circuitry 213 supplies an RF pulse corresponding to a Larmor frequency, etc. to the transmitter coil 215 under the control of the sequence control circuitry 221.

The receiver coil 217 is an RF coil arranged inside the gradient field coil 203. The receiver coil 217 receives an MR signal emitted from the subject P through the radio-frequency field. The receiver coil 217 outputs the received MR signal to the reception circuitry 219. The receiver coil 217 is a coil array including, for example, one or more, typically a plurality, of receiver coil elements. The receiver coil 217 is, for example, a phased-array coil.

The reception circuitry 219 generates, under the control of the sequence control circuitry 221, a digital MR signal, which is digitized complex data, based on the MR signal output from the receiver coil 217. Specifically, the reception circuitry 219 subjects the MR signal output from the receiver coil 217 to a variety of signal processing, and then performs analog-to-digital (A/D) conversion on data that has been subjected to the variety of signal processing. The reception circuitry 219 samples the A/D-converted data. Thereby, the reception circuitry 219 generates a digital MR signal (hereinafter referred to as “MR data”). The reception circuitry 219 outputs the generated MR data to the sequence control circuitry 221.

The sequence control circuitry 221 controls the gradient field power supply 205, the transmission circuitry 213, the reception circuitry 219, etc., in accordance with an examination protocol output from the processing circuitry 231, and performs imaging on the subject P. An examination protocol includes various pulse sequences, namely, imaging sequences corresponding to the examination.

The bus 223 is a transmission path for transmitting data between the interface 225, the display 227, the storage apparatus 229, and the processing circuitry 231. The bus 223 may be connected via, for example, a network to physiological signal measuring equipment, an external storage apparatus, and modalities of various kinds. For example, an electrocardiograph (unillustrated) is connected to the bus as physiological signal measuring equipment.

The interface 225 includes circuitry that

receives various instructions and information inputs from a user. The interface 225 includes, for example, circuitry relating to a pointing device such as a mouse or an input device such as a keyboard. The circuit included in the interface 225 is not limited to a circuit relating to a physical operational component, such as a mouse or a keyboard. For example, the interface 225 may include an electrical signal processing circuit which receives an electrical signal corresponding to an input operation from external input equipment provided separately from the MRI apparatus 20 and outputs the received electrical signal to various circuits.

The display 227 displays, for example, various magnetic resonance (MR) images generated by an image generating function 2313, and various types of information relating to imaging and image processing, under the control of a system control function 2311 in the processing circuitry 231. The display 227 is, for example, a CRT display, a liquid crystal display, an organic EL display, an LED display, a plasma display, or any other display or monitor known in the present technical field.

The storage apparatus 229 stores, for example, MR

data filled in in a k-space through the image generating function 2313, and image data generated by the image generating function 2313. The storage apparatus 229 stores various types of examination protocols, conditions for imaging etc., including a plurality of imaging parameters that define examination protocols. The storage apparatus 229 stores programs corresponding to various functions that are implemented by the processing circuitry 231. The storage apparatus 229 is, for example, a semiconductor memory element, such as a random access memory (RAM) and a flash memory, a hard disk drive, a solid-state drive, or an optical disk, etc. Also, the storage apparatus 229 may be, for example, a drive that reads and writes various kinds of information from and to a portable storage medium such as a CD-ROM drive, a DVD drive, or a flash memory.

The processing circuitry 231 includes, as hardware resources, a processor (unillustrated) and a memory such as a read-only memory (ROM) and a RAM, and collectively controls the MRI apparatus 20. The processing circuitry 231 includes a system control function 2311, an image generating function 2313, an obtaining function 101, a converting function 102, an executing function 103, a training function 104, and a display control function 105.

With the system control function 2311, the processing circuitry 231 performs control to apply an excitation pulse in accordance with the excitation pulse sequence and to apply a gradient field. With the system control function 2311, the processing circuitry 231 executes an excitation pulse sequence, and then acquires an MR signal from the subject P in accordance with a data acquisition sequence, which is a pulse sequence for acquiring various data, and thereby generates MR data.

With the image generating function 2313, the processing circuitry 231 fills in MR data along a readout direction of k-space in accordance with a strength of the readout gradient field. The processing circuitry 231 generates an MR image by performing a Fourier transform on the MR data filled in in the k-space. For example, the processing circuitry 231 can generate an absolute value (magnitude) image from complex MR data. Also, the processing circuitry 231 can generate a phase image using real-part data and imaginary-part data in the complex MR data.

On the other hand, the operations of the

functions such as the obtaining function 101, the converting function 102, the executing function 103, the training function 104, and the display control function 105 are similar to those of the data generation apparatus 1. Specifically, in this example, the processing circuitry 10 directly obtains, with the obtaining function 101, an operation instruction made by the MRI apparatus 20 via the interface 225, as well as MRI data actually acquired by the system control function 2311, and converts, with the converting function 102, the operation instruction into an internal instruction. For example, by applying the third example of the conversion process shown in FIG. 5, the converting function 102 may directly incorporate an internal instruction for each piece of hardware of the MRI apparatus 20 (e.g., the static field magnet 201, the gradient field coil 203, the gradient field power supply 205, the couch 207, the couch control circuitry 209, the transmission circuitry 213, the transmitter coil 215, the receiver coil 217, the reception circuitry 219, and the sequence control circuitry 221). With the executing function 103, the processing circuitry 10 inputs at least an internal instruction to the simulator 32 to be installed, and generates simulation data.

Such various functions of the processing circuitry 231 are stored in the storage apparatus 229 in the form of a program executable by a computer. The processing circuitry 231 is a processor configured to read programs corresponding to the respective functions from the storage apparatus 229 and execute the programs to realize the functions corresponding to the programs. In other words, after reading the programs, the processing circuitry 231 is equipped with the functions, etc. shown in the processing circuitry 231 of FIG. 1.

FIG. 6 illustrates a case where the various functions are realized in a single piece of processing circuitry 231; however, the processing circuitry 231 may be configured by a combination of a plurality of independent processors, and the functions may be realized by execution of the programs by the processors. In other words, each of the above-mentioned functions may be configured as a program, and a single piece of processing circuitry may execute each program, or a specific function may be implemented in exclusive, independent program-execution circuitry.

According to the present embodiment described above, the user's operation instruction is converted into an internal instruction relating to hardware control of the actual image diagnostic apparatus, and a simulation relating to data acquisition is executed based on a physical simulator using the internal instruction. By executing a simulation based on an instruction for hardware control corresponding to an imaging condition input by the user, it is possible to provide a simulator with information for reproducing the behavior of the actual apparatus in the simulator. As a result, the simulator can simulate the behavior of the image diagnostic apparatus with high precision, thereby generating simulation data according to the actually measured data.

The term “processor” used herein refers to, for example, circuitry such as a central processing unit (CPU), a graphics processing unit (GPU), an application-specific integrated circuit (ASIC), or a programmable logic device (e.g., a simple programmable logic device (SPLD), a complex programmable logic device (CPLD), or a field programmable gate array (FPGA)). If the processor is, for example, a CPU, the processor reads and executes the programs stored in storage circuitry to implement the functions. If the processor is, for example, an ASIC, the functions are directly incorporated into the circuitry of the processor as logic circuitry, instead of the programs being stored in the storage circuitry. Each processor in the present embodiment is not limited to a single circuitry-type processor, and multiple independent circuits may be combined and integrated as a single processor to realize the intended functions. Furthermore, the functions may be implemented by a single processor into which multiple components shown in the drawings are incorporated.

In addition, the functions according to the embodiment may be implemented by installing a program for executing the process into a computer such as a workstation and expanding the program on the memory. At this time, the program capable of causing the computer to execute such an approach may be stored in a storage medium such as a magnetic disk (hard disk), an optical disk (a CD-ROM, a DVD, etc.), a semiconductor memory, etc., and distributed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A data generation apparatus comprising processing circuitry configured to:
obtain an operation instruction based on a user operation on an image diagnostic apparatus or an image diagnostic apparatus simulator;
convert the operation instruction into an internal instruction relating to hardware control of the image diagnostic apparatus or the image diagnostic apparatus simulator from which the operation instruction has been obtained; and
generate simulation data by executing a physical simulation using the internal instruction.

2. The data generation apparatus according to claim 1, wherein
the internal instruction includes information relating to magnitudes of a voltage and a current supplied to hardware driven to realize the operation instruction, or logical values associated with the magnitudes of the voltage and the current, and application times of the voltage and the current.

3. The data generation apparatus according to claim 1, wherein
the processing circuitry is configured to record the internal instruction.

4. The data generation apparatus according to claim 1,
the processing circuitry is configured to execute a part of the internal instruction.

5. The data generation apparatus according to claim 1, wherein
the processing circuitry is configured to execute the physical simulation based on the internal instruction using a simulator in which phantom data is set.

6. The data generation apparatus according to claim 1, wherein
the processing circuitry is configured to convert a log file relating to inspection information of the image diagnostic apparatus into the internal instruction.

7. The data generation apparatus according to claim 1, wherein
the processing circuitry is configured to obtain, from a log file relating to a hardware instruction for operating hardware in the image diagnostic apparatus, the hardware instruction as the internal instruction.

8. The data generation apparatus according to claim 1, wherein
the processing circuitry is configured to execute the physical simulation by directly obtaining, from the image diagnostic apparatus, a hardware instruction for operating hardware in the image diagnostic apparatus as the internal instruction.

9. The data generation apparatus according to claim 1, wherein
the processing circuitry is further configured to:
generate a trained model by training a model using the simulation data as training data.

10. A data generation method comprising:
obtaining an operation instruction based on a user operation on an image diagnostic apparatus or an image diagnostic apparatus simulator;
converting the operation instruction into an internal instruction relating to hardware control of the image diagnostic apparatus or the image diagnostic apparatus simulator from which the operation instruction has been obtained; and
generating simulation data by executing a simulation relating to data acquisition using the internal instruction.

11. A non-transitory computer readable medium including computer executable instructions, wherein the instructions, when executed by a processor, cause the processor to perform a method comprising:
obtaining an operation instruction based on a user operation on an image diagnostic apparatus or an image diagnostic apparatus simulator;
converting the operation instruction into an internal instruction relating to hardware control of the image diagnostic apparatus or the image diagnostic apparatus simulator from which the operation instruction has been obtained; and
generating simulation data by executing a simulation relating to data acquisition using the internal instruction.

12. A magnetic resonance imaging apparatus on which a simulator is installed, comprising:
a console configured to accept an operation relating to acquisition of a magnetic resonance signal including an imaging sequence from a user; and
processing circuitry configured to:
acquire the magnetic resonance signal based on the operation;
convert the operation into an internal instruction relating to hardware control of the magnetic resonance imaging apparatus; and
execute a simulation relating to acquisition of the magnetic resonance signal by inputting the internal instruction to the simulator, and generate simulation data.

13. The magnetic resonance imaging apparatus according to claim 12, wherein
the operation includes an operation relating to setting of a pulse sequence, and
the internal instruction includes an instruction relating to a gradient field, a voltage and a current to be applied to a transmitter coil and a receiver coil, and application times of the voltage and the current.
